(19) United States
(12) Patent Application Publication
(10) Pub. No.: US 2017/0186581 A1
(43) Pub. Date: Jun. 29, 2017

(54) ION SOURCE

(71) Applicant: FINE SOLUTION CO., LTD., Suwon-si (KR)

(72) Inventors: Yun Seok HWANG, Seoul (KR); Yun Sung HUH, Anyang-si (KR)

(73) Assignee: FINE SOLUTION CO., LTD., Suwon-si (KR)

(21) Appl. No.: 15/417,052

(22) Filed: Jan. 26, 2017

Related U.S. Application Data
(63) Continuation of application No. PCT/KR2015/005546, filed on Jun. 3, 2015.

(30) Foreign Application Priority Data
Jul. 29, 2014 (KR) 10-2014-0096143
Sep. 6, 2014 (KR) 10-2014-0119496

(51) Int. Cl. H01J 37/08; H01J 37/32

(52) U.S. Cl. CPC H01J 37/08; H01J 37/32422; H01J 37/32449

(57) ABSTRACT

An ion source includes a magnetic field portion and an electrode. The magnetic field portion has an open side directing toward a workpiece and a closed side. An inner magnetic pole and an outer magnetic pole are disposed to be spaced apart from each other at the open side and the closed side is connected to a magnetic core, so that an accelerating closed loop of plasma electrons is formed at the open side. The inner magnetic pole has a gas injection portion configured to supply gas toward the accelerating closed loop. The electrode is disposed at a lower portion of the acceleration closed loop with being spaced apart from the magnetic field portion.

### TECHNICAL FIELD

The present disclosure relates to an ion source and, more particularly, to an ion source having a gas injection portion at a magnetic pole.

### BACKGROUND ART

Ion sources are being utilized usefully for a substrate modification or a thin film deposition. The ion source has a structure that forms a closed drift loop using electrodes and magnetic poles so that electrons move at high speeds along the loop. A working gas, that is, a gas to be ionized is supplied continuously from outside of a process chamber into the closed drift loop in which electrons move.

An ion source disclosed in U.S. Pat. No. 7,425,709 includes a gas distribution plate and gas distribution members for supplying the gas from the outside into the ion source. Generally, conventional ion sources receives the gas from the outside through such gas distribution members and produces a plasma to inject plasma ions by diffusion caused by an internal and external pressure difference.

The conventional ion source, however, has a drawback that electrode surfaces may be etched away during the production of the plasma ions. Etched-away particles of metal, silicon dioxide, and the like may be injected to the outside together with the plasma ions, which may cause a contamination of a workpiece by impurities. Also, the particles may adhere to the electrodes to be accumulated on the electrodes, and generate arcs between the electrodes. Such impurities and arcs may degrade the performance of the ion source and deteriorate subsequent experiments or processes.

A method for solving the problem is switching of the polarities of the electrodes, which is disclosed in U.S. Pat. Nos. 6,750,600 and 6,870,164, and Korean laying-open patent publication No. 10-2011-0118622.

However, such a method requires an additional configuration for switching the polarities of a power supply. The additional configuration brings about more complicated structure and higher manufacturing costs. Moreover, the switching of the polarities may show limited performance in the removal of the particles deposited on the electrodes or the magnetic poles.

### DISCLOSURE OF INVENTION

### Technical Problem

The present disclosure is directed to solving the above problem.

The present disclosure provides an ion source that may minimize the deposition of impurities on a substrate, electrodes, magnetic poles, and the like.

The present disclosure provides an ion source that allows control of a density of ions in a process chamber.

The present disclosure provides an ion source that may minimize arcs and particles caused by the arcs.

The present disclosure provides an ion source that facilitates smooth and rapid migrations of plasma ions to the substrate.

### Technical Solution

According to an aspect of the present disclosure to achieve the above objects, an ion source includes a magnetic field portion and an electrode.

The magnetic field portion has an open side directing toward a workpiece and a closed side. An inner magnetic pole and an outer magnetic pole are disposed to be spaced apart from each other at the open side and the closed side is connected to a magnetic core, so that an accelerating closed loop of plasma electrons is formed at the open side. The inner magnetic pole has a gas injection portion configured to supply gas toward the accelerating closed loop.

The electrode is disposed at a lower portion of the acceleration closed loop with being spaced apart from the magnetic field portion.

The gas injection portion may include a gas inlet, a gas distribution portion, and a first gas injection portion.

The gas inlet is configured to receive a gas from outside.

The gas distribution portion is connected to the gas inlet in fluid communications and formed along a longitudinal direction of the inner magnetic pole, and has a greater cross-section than the gas inlet.

The first gas injection portion is formed along the longitudinal direction of the inner magnetic pole, and has an end connected to the gas distribution portion in fluid communications and another end that is open toward the accelerating closed loop. The first gas injection portion is configured to be a slit shape having a smaller cross-section than the gas distribution portion so as to inject the gas toward the accelerating closed loop.

The gas injection portion may include a second gas injection portion. The second gas injection portion, which may be formed along the longitudinal direction of the inner magnetic pole, has an end connected to the gas distribution portion in fluid communications and another end being open toward the workpiece. The second gas injection portion has a smaller cross-section than the gas distribution portion so as to inject the gas toward the workpiece.

The second gas injection portion may include a plurality of through holes or consecutive slits.

According to another aspect of the present disclosure to achieve the above objects, an ion source includes a magnetic field portion, a gas injecting extension, and an electrode.

The magnetic field portion is configured to have an open side directing toward a workpiece and another side. The inner magnetic pole and an outer magnetic pole are disposed to be spaced apart from each other at the open side. The another side is connected to a magnetic core. The magnetic field portion can form a plasma ignition and electron acceleration region at the open side. The inner magnetic pole or the outer magnetic pole has a gas injection portion that has a side that is open toward the workpiece.

The gas injecting extension is coupled to but electrically insulated from the inner magnetic pole or the outer magnetic pole. The gas injecting extension is connected to the gas injection portion in fluid communications and protrudes toward the workpiece.

The electrode is disposed in the magnetic field portion with being spaced apart from the inner magnetic pole and the outer magnetic pole.

The gas injecting extension may be made from an electrically isolating material.

The gas injecting extension may include an electrically-insulating member and a piping member.

The electrically-insulating member may be coupled to the inner magnetic pole or the outer magnetic pole. The electrically-insulating member may have a first though hole connected to the gas injection portion in fluid communications.

The piping member may be coupled to the electrically-insulating member. The piping member may have an end connected to the first though hole in fluid communications and another end being open toward the workpiece.

The piping member may have a recess in a boundary region contacting with the electrically-insulating member.

The electrically-insulating member may have a recess in a boundary region contacting with the piping member, the inner magnetic pole, or the outer magnetic pole.

The plasma ignition and electron acceleration region may form multiple closed loops.

The ion source may include a power distributor. In a multi-loop ion source having multiple electrodes, the power distributor may generate a DC, AC, or pulsed output voltage and output to the multiple electrodes.

The gas injection portion may include a gas inlet, a gas distribution portion, and a gas injection portion.

The gas inlet is configured to receive a gas from outside.

The gas distribution may be connected to the gas inlet in fluid communications and formed along a longitudinal direction of the inner magnetic pole or the outer magnetic pole, and have a greater cross-section than the gas inlet.

The gas injection portion is formed along the longitudinal direction of the inner magnetic pole or the outer magnetic pole, and has an end connected to the gas distribution portion in fluid communications and another end being open toward the workpiece. The gas injection portion may have a smaller cross-section than the gas distribution portion. The gas injection portion may include a plurality of through holes or consecutive slits.

According to another aspect of the present disclosure, is provided a deposition apparatus that includes a process chamber, an ion source, a first and second gas injectors.

The process chamber defines a closed interior space in the deposition apparatus.

The ion source is installed in the process chamber. The ion source includes a magnetic field portion, a gas injecting extension, and an electrode. The magnetic field portion has an open side directing toward a workpiece and another side. An inner magnetic pole and an outer magnetic pole are disposed to be spaced apart from each other at the open side and the another side is connected to a magnetic core, so that a plasma ignition and electron acceleration region is formed at the open side. The inner magnetic pole or the outer magnetic pole has a gas injection portion having a side that is open toward the workpiece. The gas injecting extension is coupled to but electrically insulated from the inner magnetic pole or the outer magnetic pole. The gas injecting extension is connected to the gas injection portion in fluid communications and protrudes toward the workpiece. The an electrode is disposed in the magnetic field portion with being spaced apart from the inner magnetic pole and the outer magnetic pole.

The first gas injector may inject a reaction gas or a deposition gas through the gas injection portion.

The second gas injector may inject a process gas into the process chamber.

The plasma ignition and electron acceleration region may be configured to form multiple closed loops.

The deposition apparatus may include a power distributor. In a multi-loop configuration having multiple electrodes, the power distributor may generate a DC, AC, or pulsed output voltage and output the output voltage to the multiple electrodes.

### Advantageous Effects

The ion source having such a configuration may minimize the generation of etching contaminants in the ion source itself, and prevent the etching contaminants from being deposited on the electrodes or magnetic poles of the ion source. In addition, it is possible to block the deposition of the contaminants on a substrate on which only the desired material is to be deposited.

Exemplary embodiments of the present disclosure can feed an ion density control gas in addition to the gas to control an ion density, which may enhance a process efficiency.

Exemplary embodiments of the present disclosure can make a flow stream which facilitates the move of plasma ions to the substrate, and may increase a substrate deposition rate of the plasma ions.

### DESCRIPTION OF DRAWINGS

FIGS. 1A and 1B are a perspective view and a cross-sectional view, respectively, of an ion source according to a first embodiment.

FIGS. 2A and 2B are a perspective view and a cross-sectional view, respectively, of an ion source according to a second embodiment.

FIGS. 3A and 3B are a perspective view and a cross-sectional view, respectively, of an ion source according to a third embodiment.

FIGS. 4A and 4B are a perspective view and a cross-sectional view, respectively, of an ion source according to a fourth embodiment.

FIGS. 5A and 5B are a perspective view and a cross-sectional view, respectively, of an ion source according to a fifth embodiment.

FIGS. 6A and 6B are a perspective view and a cross-sectional view, respectively, of an ion source according to a sixth embodiment.

FIGS. 7A and 7B are a perspective view and a cross-sectional view, respectively, of an ion source according to a seventh embodiment.

FIGS. 8A and 8B are a perspective view and a cross-sectional view, respectively, of an ion source according to an eighth embodiment.

FIGS. 9A and 9B are a perspective view and a cross-sectional view, respectively, of an ion source according to a ninth embodiment.

FIGS. 10A and 10B are a perspective view and a cross-sectional view, respectively, of an ion source according to a tenth embodiment.

FIGS. 11A through 11D are cross-sectional views illustrating modifications of a gas injecting extension of an ion source of the present disclosure.

FIGS. 12A and 12B are a perspective view and a cross-sectional view, respectively, of an ion source according to an eleventh embodiment.

FIGS. 13A and 13B are a perspective view and a cross-sectional view, respectively, of an ion source according to a twelfth embodiment.

FIGS. 14A and 14B are a perspective view and a cross-sectional view, respectively, of an ion source according to a thirteenth embodiment.

FIGS. 15A and 15B are a perspective view and a cross-sectional view, respectively, of an ion source according to a fourteenth embodiment.

FIG. 16 illustrates a deposition apparatus including an ion source according the present disclosure.

### BEST MODE

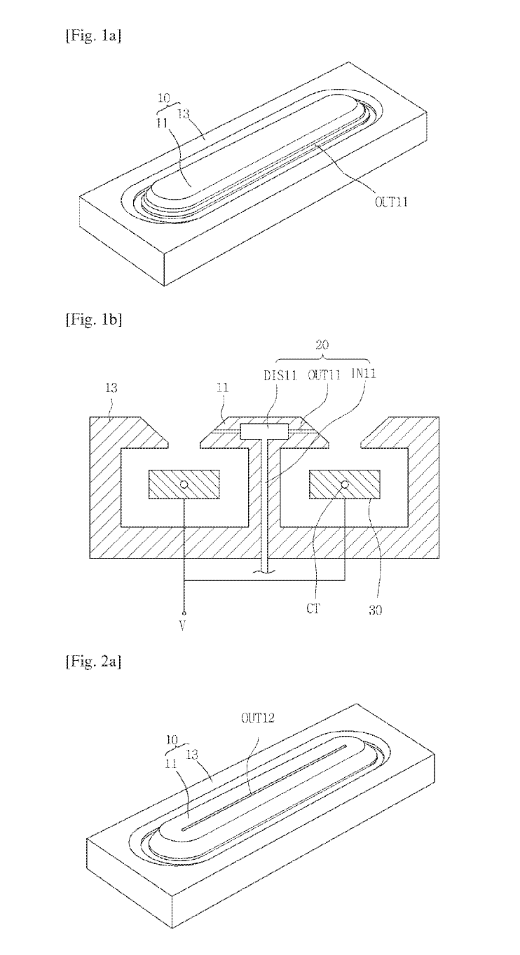

FIGS. 1A and 1B are a perspective view and a cross-sectional view, respectively, of an ion source according to a first embodiment of the present disclosure.

The ion source according to the first embodiment may include a magnetic field portion 10, an inner gas injection portion 20, and an electrode 30.

The magnetic field portion 10 is open at a front side facing a substrate, and closed at lateral and rear sides. An inner magnetic pole 11 and an outer magnetic pole 13 which are displaced apart from each other are disposed on the open side. A magnet may be provided at a lower position of the inner magnetic pole 11. For example, the magnet may be disposed in such a manner that the inner magnetic pole 11 may have a polarity of the N pole and the outer magnetic pole 13 may have a polarity of the S pole.

A magnetic core that is coupled integrally or detachably to the inner and outer magnetic poles 11 and 13 may be provided on the closed sides. Here, the magnetic core may mean an entire rear part of the magnetic field portion 10 excluding the inner magnetic pole 11 and the outer magnetic pole 13 that forms an accelerating closed loop on the open side. The outer magnetic pole 13 may be magnetically coupled to the S pole of the magnet through the magnetic core to have the polarity of the S pole. The magnetic core is a path through which the magnetic force lines of the S pole existing at the lower end of the magnet pass through and may be made of a material having high magnetic permeability. The magnetic core may also perform a function of limiting a magnetic field distribution of the magnet, that is, an interaction of the magnetic force lines of the S pole exiting at the lower end of the magnet with the magnetic force lines of the N pole existing at the upper end of the magnet.

The inner magnetic pole 11 may include the inner gas injection portion 20 that supplies a gas toward the accelerating closed loop. As shown in FIG. 1B, the inner gas injection unit 20 may include an inner gas inlet IN11, an inner gas distribution portion DIS11, and an inner lateral gas injection portion OUT11.

The inner gas inlet IN11 is configured to receive the gas from the outside. The inner gas inlet IN11 may be a through hole having a circular or polygonal cross-section that penetrates the inner magnetic pole 11 or be implemented by inserting a separate tube having the circular or polygonal cross-section into the through hole. Depending on the size of the ion source, a plurality of the inner gas inlets IN11 may be provided in the ion source with being spaced apart by a predetermined distance.

The gas injected through the inner gas inlet IN11 may be an inert gas such as argon (Ar), a reactive gas such as oxygen (O2) and nitrogen (N2), or a thin-film forming gas such as acetic acid (CH3COOH), methane (CH4), tetrafluoromethane (CF4), silane (SiH4), ammonia (NH3), tri-methyl aluminum (TMA), or a combination of them.

The inner gas distribution portion DIS11 is connected to the inner gas inlet IN11 in fluid communications and may have a circular or polygonal cross-section. The inner gas distribution portion DIS11 may be formed along a longitudinal direction of the inner magnetic pole 11. The inner gas distribution portion DIS11 may have a greater cross-section than the inner gas inlet IN11. The inner gas distribution portion DIS11 may distribute the gas flowing through the inner gas inlet IN11 uniformly over an entire inner space of the inner magnetic pole 11.

The inner lateral gas injection portion OUT11 may elongate along the edge or front face of the inner magnetic pole 11. One end of the inner lateral gas injection portion OUT11 may be connected to the inner gas distribution portion DIS11 in fluid communications, and the other end thereof may be open to the accelerating closed loop. The inner lateral gas injection portion OUT11 may have a smaller cross-section than the inner gas distribution portion DIS11. Accordingly, the inner lateral gas injection portion OUT11 may inject the gas in the gas distribution portion DIS11 toward the accelerating closed loop. The inner lateral gas injection portion OUT11 may be implemented by consecutive slits or a plurality of through holes.

The electrode 30 may be disposed between the inner magnetic pole 11 and the outer magnetic pole 13, or be positioned under the accelerating closed loop to be spaced apart from the magnetic field portion 10.

A power source V, which is connected to the electrode 30, may supply an alternating current (AC) or direct current (DC) high voltage power.

When the high voltage power is applied to the electrode 30, a large amount of heat is generated in the electrode 30. In order to emit the heat, the electrode 30 may include a cooling channel which may be formed by machining the electrode 30, or a cooling tube CT. The cooling channel or the cooling tube CT can be made of a metal having a high electrical conductivity and thermal conductivity. Cooling water flows through the cooling channel or the cooling tube CT.

The ion source shown in FIGS. 1A and 1B operates as follows. The ion source may generate the accelerating closed loop of a raceway shape or circular shape between the inner magnetic pole 11 and the outer magnetic pole 13 by a magnetic field and an electric field created by the magnetic field portion 10 and the electrode 30, respectively. In the accelerating closed loop, the electrons move at a high speed and collide with the gas and, as a result, the plasma ions are produced from the gas.

A high potential difference near the electrode 30 creates plasma electrons from the gas, and the magnetic field and the electric field activate the plasma in the space of the accelerating closed loop. The plasma electrons having negative charges are subject to a cyclotron motion, and the plasma ions having positive charges pop out by the electric field to a substrate located outside the open side. The plasma ions of positive charges move to the substrate with a high kinetic energy to transfer the energy to the surface of the substrate or destroy molecular bonding beneath the surface of the substrate.

According to the first embodiment, little plasma ions or electrons are produced inside the ion source since the gas is not supplied from the rear of the electrode 30 but injected at the end of the inner magnetic pole 11 toward the accelerating closed loop. Since the plasma ions are produced near the open side and then transported to the substrate by the electric field, the etching of the inner wall of the electrode or the arcs caused by the accumulation of the impurities may be prevented.

Mode of Invention

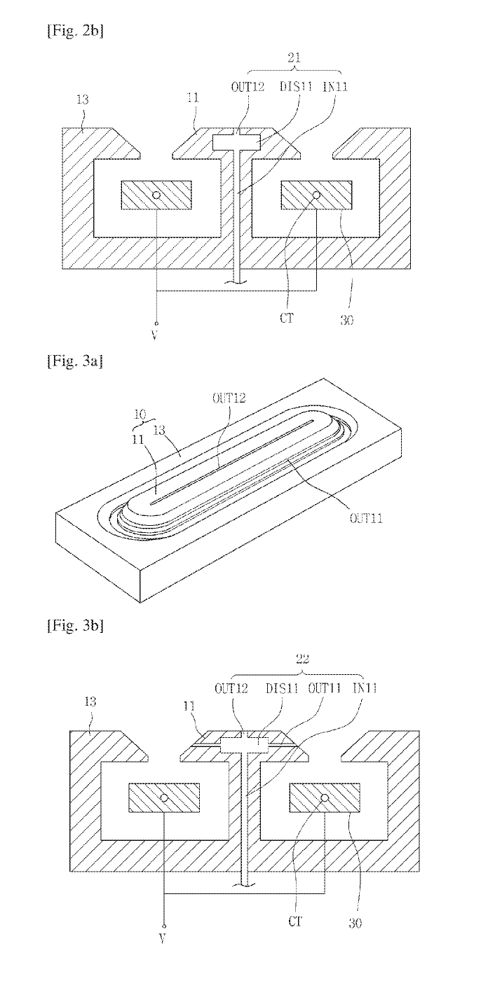

FIGS. 2A and 2B are a perspective view and a cross-sectional view, respectively, of the ion source according to a second embodiment.

In the ion source of the second embodiment shown in FIGS. 2A and 2B, an inner gas injection unit 21 may not include the inner lateral gas injection portion OUT11 that is open toward the accelerating closed loop, but may include an inner front gas injection portion OUT12 that is open toward the substrate.

The inner front gas injection portion OUT12 may be formed along the longitudinal direction of the inner magnetic pole 11. One end of the inner front gas injection portion OUT12 is connected to the inner gas distribution portion DIS11 in fluid communications and the other end of the inner front gas injection portion OUT12 is open toward the substrate. The inner front gas injection portion OUT12 has a smaller cross-section than the inner gas distribution portion DIS11 so as to inject the gas in the gas distribution portion DIS11 toward the substrate. The inner front gas injection portion OUT12 may be implemented by consecutive slits or a plurality of through holes spaced apart by a predetermined spacing.

The gas injected through the inner front gas injection portion OUT12 may form a gas flow stream in a direction toward the substrate. The gas flow stream may serve as a guide for guiding the plasma ions produced in the accelerating closed loop to the substrate, thereby improving the efficiency of a process such as a deposition process.

The gas injected through the inner gas inlet IN11 may be the inert gas such as argon (Ar). However, the gas may also be the reactive gas such as oxygen (O2) and nitrogen (N2) or the thin-film forming gas such as acetic acid (CH3COOH), methane (CH4), tetrafluoromethane (CF4), silane (SiH4), ammonia (NH3), and tri-methyl aluminum (TMA), as well.

The other configuration and features of the second embodiment are the same as or similar to the first embodiment except the inner lateral gas injection portion OUT11, descriptions thereof are omitted for simplicity of explanation.

FIGS. 3A and 3B are a perspective view and a cross-sectional view, respectively, of the ion source according to a third embodiment.

Referring to FIGS. 3A and 3B, an inner gas injection unit 22 according to the third embodiment may include both the inner lateral gas injection portion OUT11 and the inner front gas injection portion OUT12.

Since the configuration and operation of the third embodiment is apparent from the descriptions of the inner lateral gas injection portion OUT11 in the first embodiment, the inner front gas injection portion OUT12 in the second embodiment, and the other configurations of the first embodiment, descriptions thereof are omitted for simplicity of explanation.

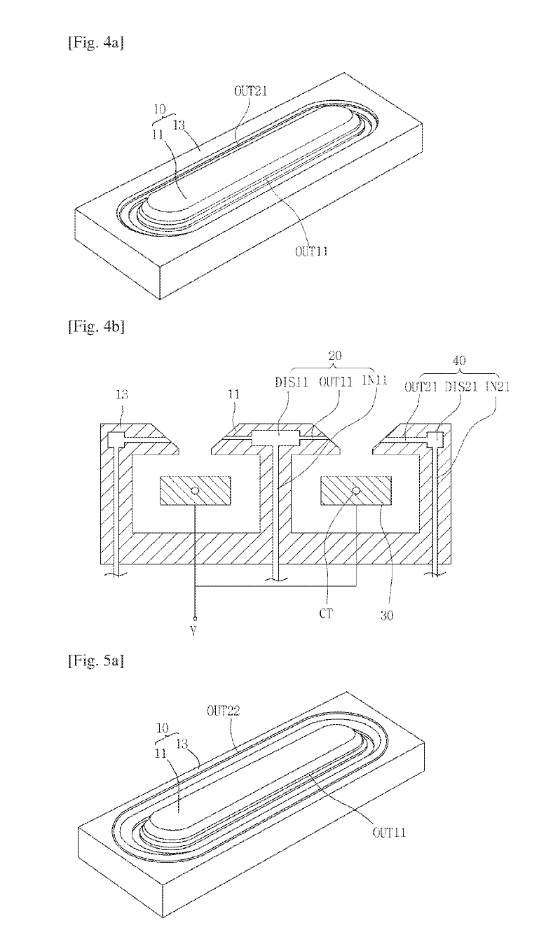

FIGS. 4A and 4B are a perspective view and a cross-sectional view, respectively, of the ion source according to a fourth embodiment.

According to the fourth embodiment shown in FIGS. 4A and 4B, the inner magnetic pole 11 may include the inner gas injection unit 20 and the outer magnetic pole 13 may include an outer gas injection unit 40.

The inner gas injection unit 20 in the fourth embodiment is the same as or similar to that in the first embodiment, and detailed description thereof is omitted here.

The outer gas injection unit 40 may include an outer gas inlet IN21, an outer gas distribution portion DIS21, and an outer lateral gas injection portion OUT21. The configurations and functions of the outer gas inlet IN21, the outer gas distribution portion DIS21, and the outer lateral gas injection portion OUT21 are the same as or similar to those of the inner gas inlet IN11, the inner gas distribution portion DIS11, and the inner lateral gas injection portion OUT11 in the first embodiment, and detailed descriptions thereof are omitted for simplicity of explanation.

However, the gas injected through the inner gas injection unit 20 and the gas injected through the outer gas injection unit 40 may be the same as or different from each other. For example, in the case that the gas fed through the inner gas injection unit 20 is different from the gas fed through the outer gas injection unit 40, the reactive gas such as oxygen (O2) and nitrogen (N2) or the thin-film forming gas such as acetic acid (CH3COOH), methane (CH4), tetrafluoromethane (CF4), silane (SiH4), ammonia (NH3), and tri-methyl aluminum (TMA) may be injected through the inner gas injection unit 20 while the inert gas such as argon (Ar) may be injected through the outer gas injection unit 40. Of course, the injection gases may be reversed as well.

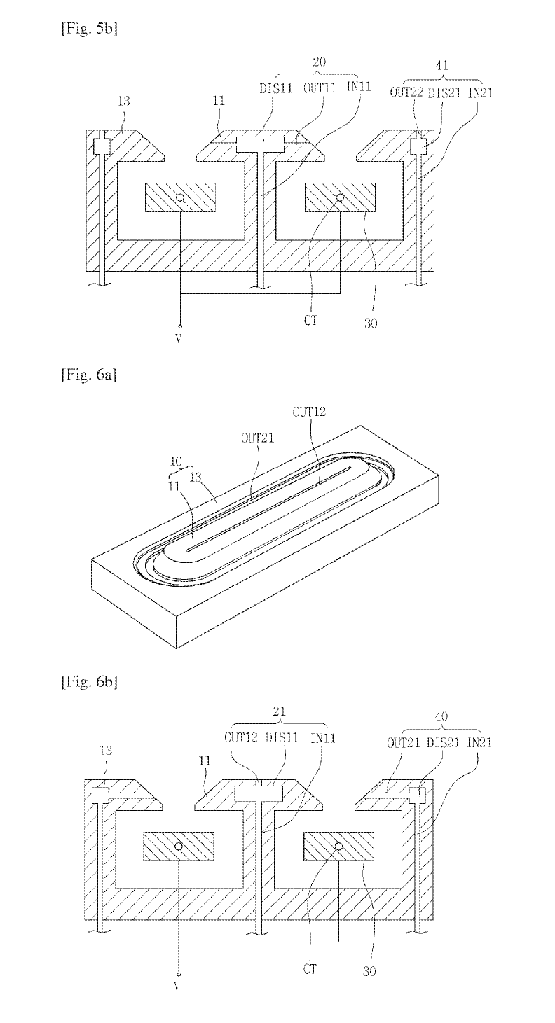

FIGS. 5A and 5B are a perspective view and a cross-sectional view, respectively, of the ion source according to a fifth embodiment.

According to the fifth embodiment shown in FIGS. 5A and 5B, the inner magnetic pole 11 may include the inner gas injection unit 20, and the outer magnetic pole 13 may include an outer gas injection unit 41.

The inner gas injection unit 20 in the fourth embodiment is the same as or similar to that in the first embodiment, and detailed description thereof is omitted here.

The outer gas injection unit 41 may include the outer gas inlet IN21, the outer gas distribution portion DIS21, and an outer front gas injection portion OUT22. The configurations and functions of the outer gas inlet IN21 and the outer gas distribution portion DIS21 are the same as or similar to those of the inner gas inlet IN11 and the inner gas distribution portion DIS11 in the first embodiment, and detailed descriptions thereof are omitted for simplicity of explanation.

Contrary to the fourth embodiment, the outer front gas injection portion OUT22 that is open toward the substrate is formed in the fifth embodiment instead of the outer lateral gas injection portion OUT21. The gas injected through the outer front gas injection portion OUT22 may form a gas flow stream in the direction toward the substrate. The gas flow stream may serve as the guide for guiding the plasma ions produced in the accelerating closed loop to the substrate, thereby improving the efficiency of the process such as the deposition process.

In this embodiment, the inert gas such as argon (Ar) may be injected through the outer gas injection unit 41.

FIGS. 6A and 6B are a perspective view and a cross-sectional view, respectively, of the ion source according to a sixth embodiment.

Referring to FIGS. 6A and 6B, the ion source according to the sixth embodiment may include the inner gas injection unit 21 that is open toward the front direction and the outer gas injection unit 40 that is open laterally.

The inner gas injection unit 20 in the sixth embodiment is the same as the inner gas injection unit 20 in the second embodiment, and detailed description of the inner gas injection unit 20 is omitted here.

The outer gas injection unit 40 in the sixth embodiment is the same as the outer gas injection unit 40 in the fourth embodiment, and detailed description of the outer gas injection unit 40 is omitted here.

FIGS. 7A and 7B are a perspective view and a cross-sectional view, respectively, of the ion source according to a seventh embodiment.

Referring to FIGS. 7A and 7B, the ion source according to the seventh embodiment may include the inner gas injection unit 21 and the outer gas injection unit 41 both of which are open toward the front direction.

The inner gas injection unit 21 in the seventh embodiment is the same as the inner gas injection unit 21 in the second embodiment, and detailed description of the inner gas injection unit 21 is omitted here.

The outer gas injection unit 41 in the seventh embodiment is the same as the outer gas injection unit 41 in the fifth embodiment, and detailed description of the outer gas injection unit 41 is omitted here.

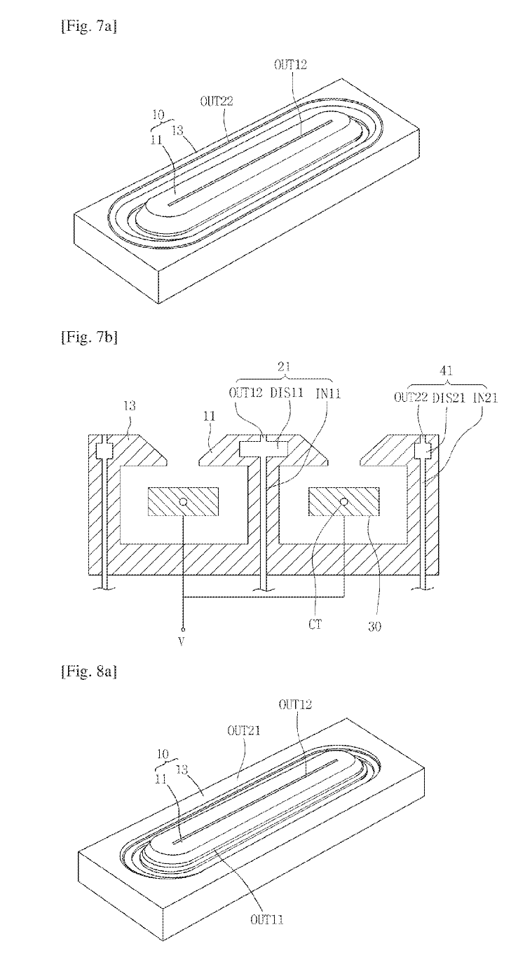

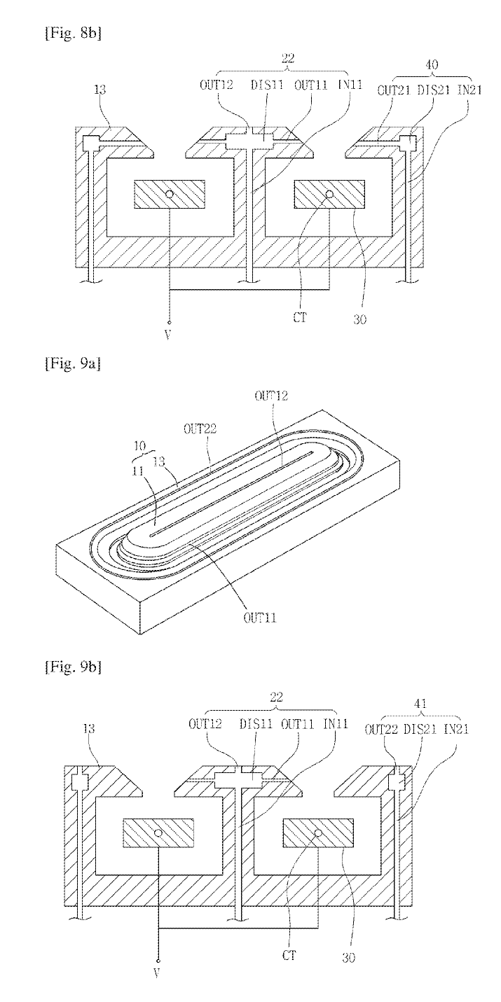

FIGS. 8A and 8B are a perspective view and a cross-sectional view, respectively, of the ion source according to an eighth embodiment.

Referring to FIGS. 8A and 8B, the ion source according to the eighth embodiment may include the inner gas injection unit 22 that is open toward the front and lateral directions and the outer gas injection unit 40 that is open laterally.

The inner gas injection unit 22 in the eighth embodiment is the same as the inner gas injection unit 22 in the third embodiment, and detailed description of the inner gas injection unit 22 is omitted here.

The outer gas injection unit 40 in the eighth embodiment is the same as the outer gas injection unit 40 in the fourth embodiment, and detailed description of the outer gas injection unit 40 is omitted here.

FIGS. 9A and 9B are a perspective view and a cross-sectional view, respectively, of the ion source according to a ninth embodiment.

Referring to FIGS. 9A and 9B, the ion source according to the ninth embodiment may include the inner gas injection unit 22 that is open toward the front and lateral directions and the outer gas injection unit 41 that is open toward the front direction.

The inner gas injection unit 22 in the ninth embodiment is the same as the inner gas injection unit 22 in the third embodiment, and detailed description of the inner gas injection unit 22 is omitted here.

The outer gas injection unit 41 in the ninth embodiment is the same as the outer gas injection unit 41 in the fifth embodiment, and detailed description of the outer gas injection unit 41 is omitted here.

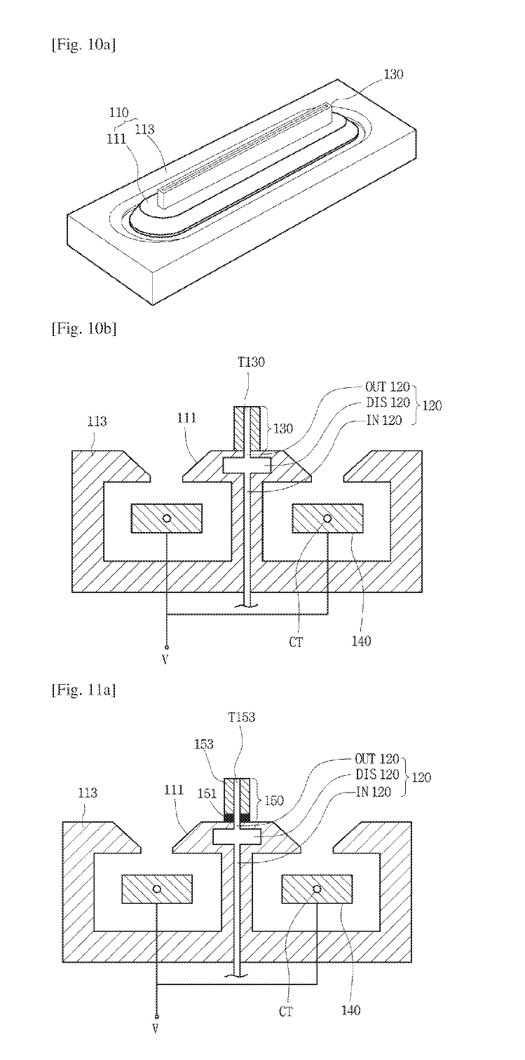

FIGS. 10A and 10B are a perspective view and a cross-sectional view, respectively, of the ion source according to a tenth embodiment.

Referring to FIGS. 10A and 10B, the ion source according to the tenth embodiment is a single loop ion source and may include a magnetic field portion 110, an inner stimulus gas injection portion 120, an inner stimulus gas injecting extension 130, and an electrode 140.

The magnetic field portion 110 is open at a front side facing the substrate, and may be closed at lateral and rear sides. An inner magnetic pole 111 and an outer magnetic pole 113 which are displaced apart from each other are disposed on the open side. A magnet may be provided at a lower position of the inner magnetic pole 111. For example, the magnet may be disposed in such a manner that the N pole of the magnet is at a upper position, so that the inner magnetic pole 111 may have the polarity of the N pole and the outer magnetic pole 13 may have the polarity of the S pole.

A magnetic core that is coupled integrally or detachably to the inner and outer magnetic poles 111 and 113 may be provided on the closed sides. FIG. 10B shows that the magnetic core is formed integrally with the inner and outer magnetic poles 111 and 113. Here, the magnetic core may mean an entire rear part of the magnetic field portion 10 excluding the inner magnetic pole 111 and the outer magnetic pole 113 forming the accelerating closed loop on the open side. The outer magnetic pole 113 may be magnetically coupled to the S pole of the magnet through the magnetic core to have the polarity of the S pole. The magnetic core is a path through which the magnetic force lines of the S pole existing at the lower end of the magnet pass through and may be made of a material having high magnetic permeability. The magnetic core may also perform a function of limiting a magnetic field distribution of the magnet, that is, an interaction of the magnetic force lines of the S pole of the magnet with the magnetic force lines of the N pole of the magnet.

The inner magnetic pole 111 may include the inner stimulus gas injection portion 120 that supplies a gas toward a substrate in front of the ion source. As shown in FIG. 10B, the inner stimulus gas injection portion 120 may include an inner stimulus gas inlet IN120, an inner stimulus gas distribution portion DIS120, and an inner stimulus gas injection portion OUT120.

Through the inner stimulus gas inlet IN120 is fed the gas from the outside. The inner stimulus gas inlet IN120 may be a through hole having a circular or polygonal cross-section that penetrates the inner magnetic pole 111 or be implemented by inserting a separate tube having the circular or polygonal cross-section into the through hole. Depending on the size of the ion source, a plurality of the inner stimulus gas inlets IN120 may be provided in the ion source to be spaced apart by a predetermined distance.

The gas injected through the inner stimulus gas inlet IN120 may be the reactive gas such as oxygen (O2) and nitrogen (N2), or the thin-film forming gas such as acetic acid (CH3COOH), methane (CH4), tetrafluoromethane (CF4), silane (SiH4), ammonia (NH3), and tri-methyl aluminum (TMA).

The inner stimulus gas distribution portion DIS120 is connected to the inner stimulus gas inlet IN120 in fluid communications and may have a circular or polygonal cross-section. The inner stimulus gas distribution portion DIS120 may be formed along a longitudinal direction of the inner magnetic pole 111. The inner stimulus gas distribution portion DIS120 may have greater a cross-section than the inner stimulus gas inlet IN120. The inner stimulus gas distribution portion DIS120 may distribute the gas flowing through the inner gas inlet IN11 uniformly over an entire inner space of the inner magnetic pole 111.

The inner stimulus gas injection portion OUT120 may be formed along the longitudinal direction of the inner magnetic pole 111. One end of the inner stimulus gas injection portion OUT120 may be connected to inner stimulus gas distribution portion DIS120, and the other end of the inner stimulus gas injection portion OUT120 may elongate to a front surface of the ion source facing the substrate. The inner stimulus gas injection portion OUT120 may have a smaller cross-section than the inner stimulus gas distribution portion DIS120 so as to inject the gas in the inner stimulus gas distribution portion DIS120 toward the substrate. The inner stimulus gas injection portion OUT120 may be implemented by consecutive slits.

The a inner stimulus gas injecting extension 130 may be coupled to the front surface of the inner magnetic pole 111. The inner stimulus gas injecting extension 130 may have a through hole T130 formed therein. One end of the through hole T130 is connected to the inner stimulus gas injection portion OUT120 in fluid communications and the other end is open outwards. The inner stimulus gas injecting extension 130 may be formed to protrude from the front face toward the substrate, i.e. upwards from the inner magnetic pole 111 in the drawing. As shown in FIGS. 10A and 10B, the inner stimulus gas injecting extension 130 may be a plate which has a slit disposed along the longitudinal direction and is open upwards and downwards in the drawing.

Though the inner stimulus gas injecting extension 130 is coupled to the inner magnetic pole 111, it may be electrically insulated from the inner magnetic pole 111. The inner stimulus gas injecting extension 130 may be formed from electrically insulating material such as ceramic, aluminum oxide, Teflon, and the like, for example.

The gas injected through the inner stimulus gas injecting extension 30 is ionized in a location away from the electrode 140 of the ion source, for example, near the substrate and is deposited on the substrate. As a result, the probability of the ions to move toward the electrode 140 is lowered, and the adhesion of the deposition ions to the electrode 140 may be minimized.

The inner stimulus gas injecting extension 130 may form a gas flow stream in the direction toward the substrate. The gas flow stream may serve as a guide for guiding the ions or the like to the substrate, thereby improving the efficiency of the process such as the deposition process.

The electrode 140 may be disposed between the inner magnetic pole 111 and the outer magnetic pole 113 in the magnetic field portion 110, or be positioned under the accelerating closed loop to be spaced apart from the magnetic field portion 110.

A power source V, which is connected to the electrode 140, may supply an AC, DC, or a pulsed power.

When high voltage power is applied to the electrode 140, a large amount of heat is generated in the electrode 140. In order to emit the heat, the electrode 140 may include a cooling channel that may be formed by machining the electrode 140 or be provided with a cooling tube CT. The cooling channel or the cooling tube CT can be made of a metal having a high electrical conductivity and thermal conductivity. Cooling water flows through the cooling channel or the cooling tube CT.

The ion source shown in FIGS. 10A and 10B operates as follows. The ion source may form the accelerating closed loop of a raceway shape between the inner magnetic pole 111 and the outer magnetic pole 113 by a magnetic field and an electric field created by the magnetic field portion 110 and the electrode 140, respectively. In the accelerating closed loop, the electrons move at a high speed and collide with a process gas such as argon (Ar) to produce argon ions (Ar+).

The electrode 140 forms an electric field which migrates the argon ions toward the substrate. The argon ions moving toward the substrate with a kinetic energy collide with a deposition gas such as silane (SiH4) injected through an upper opening of the inner stimulus gas injecting extension 30 to form deposition ions such as silicon ions (Si⁴⁻). Thereafter, The silicon ions (Si⁴⁻) are deposited on the surface of the substrate to form a silicon film.

If the ion source does not have the inner stimulus gas injecting extension 130 that protrudes toward the substrate from the inner magnetic pole 111, the silicon ions (Si⁴⁻) will move to the electrode 140 where the positive high voltage is applied, which may generate an arc between the electrode 140 and the magnetic poles 111 and 113.

FIGS. 10A and 10B depict that the inner stimulus gas injecting extension 130 has a single opening at its front opening end, but the configuration of the front opening end is not limited thereto. For example, the inner stimulus gas injecting extension 130 may further include a T-shaped flow path changing portion at the front opening end. Assuming that the direction toward the substrate is a 12 o'clock direction, the flow path changing portion may be configured to include a left shunt extending toward a direction between a 9 o'clock direction and the 12 o'clock direction and a right shunt extending toward a direction between the 12 o'clock direction and a 3 o'clock direction. The lengths of the left and right shunts would be sufficient if the shunts may change the gas injection direction. Also, the left and right shunts of the flow path changing portion may be formed to have a shape which is the same as or similar to the inner stimulus gas injecting extension 130, for example, a plate having slits therein that is open upwards and downwards.

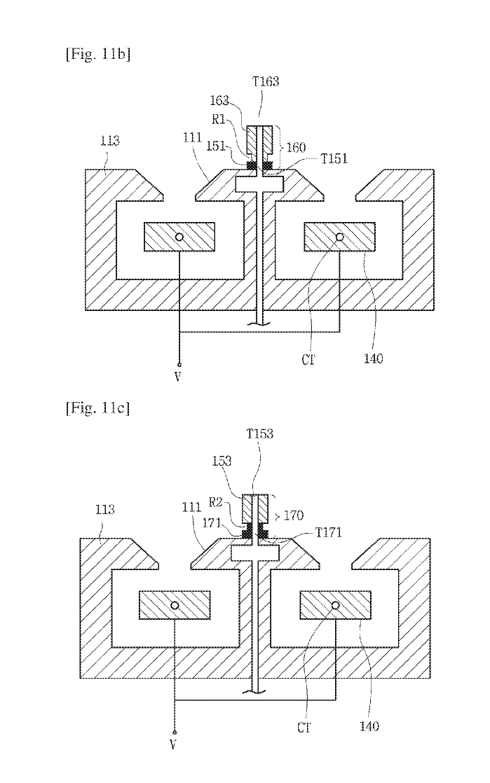

FIGS. 11A through 11D illustrate modifications of the gas injecting extension of the ion source of the present disclosure.

FIG. 11A is a cross-sectional view of a first modification of the gas injecting extension.

Referring to FIG. 11A, a gas injecting extension 150 may include an electrically-insulating member 151 and a piping member 153.

The electrically-insulating member 151 is coupled to the inner magnetic pole 111. The electrically-insulating member 151 has a through hole T151 elongated vertically. A lower end of the through hole T151 is connected to the gas injection portion OUT120 of the inner stimulus gas injection portion 120 in fluid communications, and a upper end of the through hole T151 is open upwards. The electric insulating member 151 protrudes upwards from an upper face of the inner magnetic pole 111, and may be a plate having a slit that is open upwards and downwards and extends along the longitudinal direction of the inner magnetic pole 111. The electrically-insulating member 151 may be formed from electrically insulating material such as ceramic, aluminum oxide, Teflon, and the like, for example.

The piping member 153 is installed on the electric insulating member 151. The piping member 153 has a through hole T151 elongated vertically. A lower end of the through hole T153 is connected to the through hole T151 of the electrically-insulating member 151, and a upper end of the through hole T153 is open toward the substrate. The piping member 153 protrudes from the electrically-insulating member 151 and is elongated upwards. The pipe member 153 may be a plate having a slit that is open upwards and downwards and extends in the longitudinal direction of the inner magnetic pole 111. The piping member 153 may be formed from the electrically insulating material identical to the electrically-insulating member 151, but is not limited to the electrically insulating material.

FIG. 11B is a cross-sectional view of a second modification of the gas injecting extension.

Referring to FIG. 11B, a gas injecting extension 160 may include an electrically-insulating member 151 having a through hole T151 and a piping member 163 having a through hole T163.

The second modification differs from the first modification in that a recess R1 is formed on a lower side of the piping member 163. The deposition ions, plasma ions, etching impurities and the like are hardly deposited on the recess R1. As a result, the recess R1 is helpful in electrically isolating the piping member 153 from the inner magnetic pole 111 and protecting a short circuit between the inner magnetic pole 111 and the piping member 153.

The other configuration and features of the second modification are the same as the first modification shown in FIG. 11A, descriptions thereof are omitted for simplicity of explanation.

FIGS. 11C and 11D are a cross-sectional views of a third and fourth modifications of the gas injecting extension, respectively.

Referring to FIG. 11C, a gas injecting extension 170 may include an electrically-insulating member 171 having a through hole T171 and the piping member 153 having the through hole T153. Referring to FIG. 11D, a gas injecting extension 180 may include an electrically-insulating member 181 having a through hole T181 and the piping member 153 having the through hole T153.

In the third and fourth modifications shown in FIGS. 11C and 11D, respectively, the recesses R2 and R3 are formed on a upper side or lower side of the electrically-insulating member 171 and 181 contrarily to the first modification shown in FIG. 11A. Similarly to the recess R1 of the second modification, the deposition ions, plasma ions, etching impurities and the like are hardly deposited on the recesses R2 and R3. As a result, the recesses R2 and R3 are helpful in electrically isolating the piping member 153 from the inner magnetic pole 111 and protecting a short circuit between the inner magnetic pole 111 and the piping member 153.

The other configuration and features of the third and fourth modification are the same as the first modification shown in FIG. 11A, descriptions thereof are omitted for simplicity of explanation.

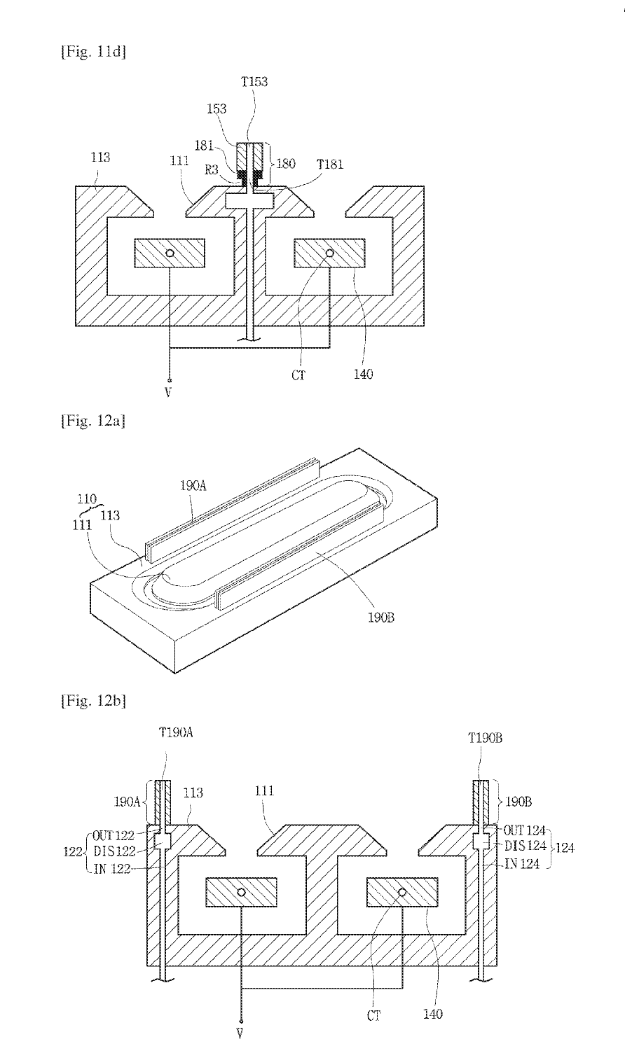

FIGS. 12A and 12B are a perspective view and a cross-sectional view, respectively, of the ion source according to an eleventh embodiment.

Contrarily to the tenth embodiment, the ion source according to the eleventh embodiment includes outer stimulus gas injecting extensions 190A and 190B. The outer stimulus gas injecting extensions 190A and 190B may be installed on linear regions of the raceway-shaped closed loop as shown in FIG. 12A. In other words, the outer stimulus gas injecting extensions 190A and 190B may be disposed in parallel on both sides of the inner magnetic pole 111 therebetween. Of course, the outer stimulus gas injecting extensions 190A and 190B may be installed in a raceway shape along the raceway-shaped closed loop.

The outer stimulus gas injecting extensions 190A and 190B may be coupled to the front surface of the outer magnetic pole 113. Each of the outer stimulus gas injecting extensions 190A and 190B may have a through hole T190A and T190B, respectively, formed therein. One end of each of the through holes T190A and T190B is connected to the outer stimulus gas injection portion OUT122 or OUT124 in fluid communications and the other end is open upwards. The outer stimulus gas injecting extensions 190A and 190B may be formed to protrude from the front face toward the substrate, i.e. upwards from the outer magnetic pole 113 in the drawing, and be a plate which has a slit disposed along the longitudinal direction and is open upwards and downwards in the drawing.

Though the outer stimulus gas injecting extensions 190A and 190B are coupled to the outer magnetic pole 113, they may be electrically insulated from the outer magnetic pole 113. The outer stimulus gas injecting extensions 190A and 190B may be formed from electrically insulating material such as ceramic, aluminum oxide, Teflon, and the like, for example.

Since the gas injected through the outer stimulus gas injecting extensions 190A and 190B is ionized near the substrate and deposited on the substrate, the probability of the ions to move toward the electrode 140 and adhere to the electrode 140 is lowered.

The outer stimulus gas injecting extensions 190A and 190B may form gas flow streams in the direction toward the substrate.

FIGS. 12A and 12B depict that each of the outer stimulus gas injecting extensions 190A and 190B has a single opening at its front opening end, but the configuration of the front opening end is not limited thereto. For example, each of the outer stimulus gas injecting extensions 190A and 190B may further include a flow path changing portion at the front opening end that is flexed toward the inner magnetic pole 111. Assuming that the direction toward the substrate is the 12 o'clock direction, a left flow path changing portion coupled to the outer stimulus gas injecting extensions 190A may extend toward a direction between the 12 o'clock direction and the 3 o'clock direction, and a right flow path changing portion coupled to the outer stimulus gas injecting extensions 190B may extend toward a direction between the 9 o'clock direction and the 12 o'clock direction. The left and right flow path changing portions may be formed to have a shape which is the same as or similar to the outer stimulus gas injecting extensions 190A and 190B, for example, a plate having slits therein that is open upwards and downwards.

The other configuration and features of the eleventh embodiment are the same as corresponding ones of the tenth embodiment, and descriptions thereof are omitted for simplicity of explanation.

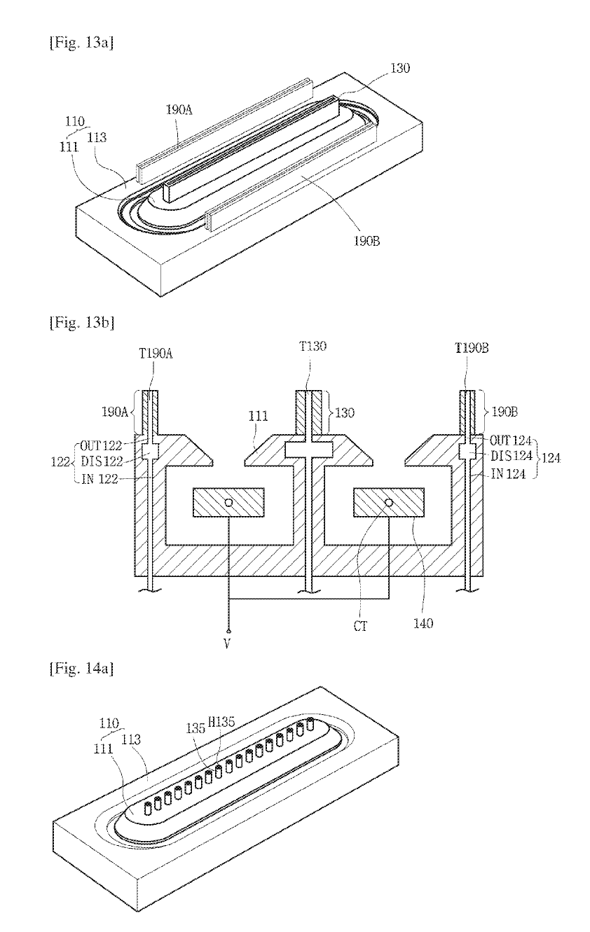

FIGS. 13A and 13B are a perspective view and a cross-sectional view, respectively, of the ion source according to a twelfth embodiment.

The ion source according to the twelfth embodiment shown in FIGS. 13A and 13B combines the features of the tenth and eleventh embodiments, and includes both the inner stimulus gas injecting extension 130 and the outer stimulus gas injecting extensions 190A and 190B.

The inner stimulus gas injecting extension 130 and the outer stimulus gas injecting extensions 190A and 190B of the twelfth embodiment may be identical to the inner stimulus gas injecting extension 130 of the tenth embodiment and the outer stimulus gas injecting extensions 190A and 190B of the eleventh embodiment, detailed descriptions thereof are omitted. Also, the other configuration and features of the twelfth embodiment are the same as corresponding ones of the tenth or eleventh embodiment, and descriptions thereof are omitted, also.

FIGS. 14A and 14B are a perspective view and a cross-sectional view, respectively, of the ion source according to a thirteenth embodiment.

Referring to FIGS. 14A and 14B, the ion source according to the thirteenth embodiment may include an inner stimulus gas injecting extension having a plurality of tubes 135 having through holes H135 rather than the plate having a slit described above regarding the tenth embodiment. The plurality of tubes 135 may be disposed on the inner magnetic pole 111 and placed apart by a predetermined spacing

In the inner stimulus gas injection portion 120 of the thirteenth embodiment, the inner stimulus gas inlet IN120 and the inner stimulus gas distribution portion DIS120 may be configured to be the same as the corresponding ones of the tenth embodiment. The inner stimulus gas injection portion OUT120 may be open upwards only in positions of the tubes 135 of the inner stimulus gas injecting extension while the other location of the front face in the inner stimulus gas injecting extension is clogged.

FIGS. 14A and 14B depict that each tube in the inner stimulus gas injecting extension 135 has a single opening at its front opening end, but the configuration of the front opening end is not limited thereto. For example, the T-shaped flow path changing portion described above with reference to the tenth embodiment may be provided further at the front opening end of the inner stimulus gas injecting extension 135. The flow path changing portion may have a shape being the same as or similar to the inner stimulus gas injecting extension 135, for example, a tube that is open upwards and downwards.

The other configuration and operation of the thirteenth embodiment are the same as corresponding ones of the tenth embodiment, and detailed descriptions thereof are omitted.

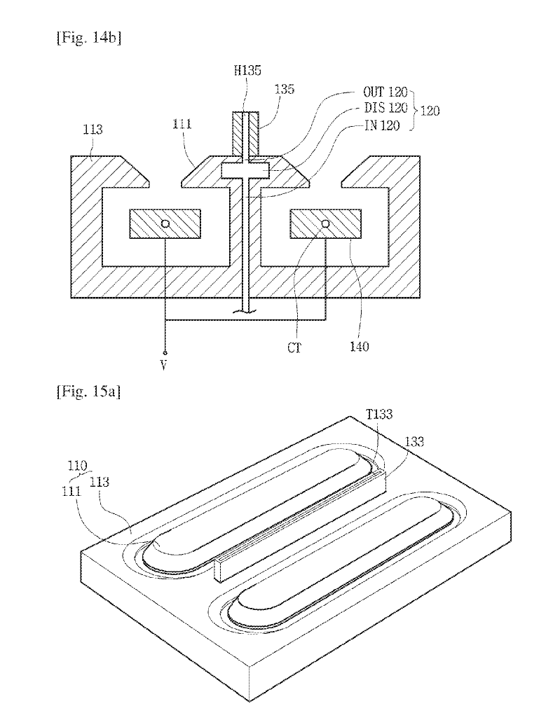

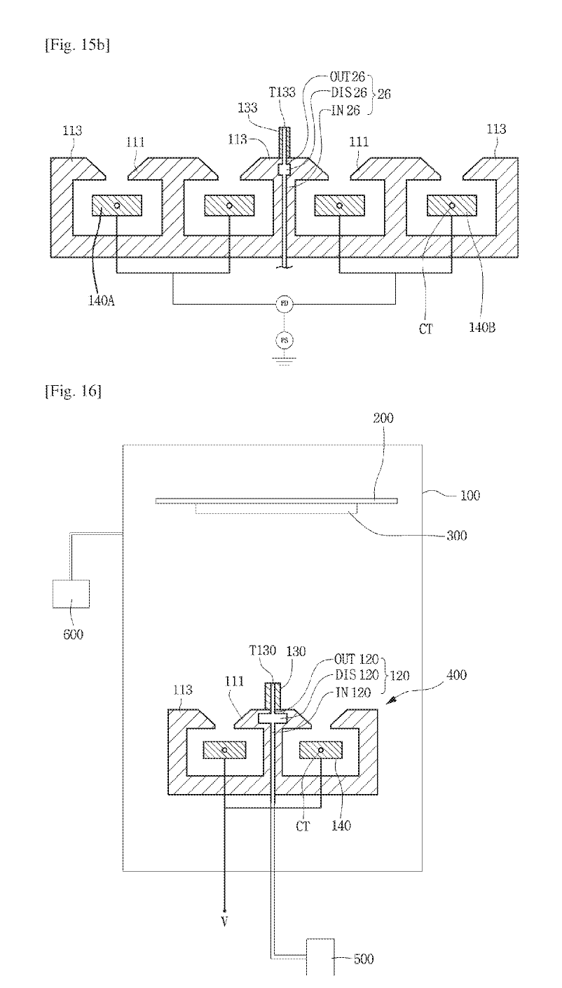

FIGS. 15A and 15B are a perspective view and a cross-sectional view, respectively, of the ion source according to a fourteenth embodiment.

The ion source of the fourteenth embodiment is a multi-loop ion source in which two single-loop ion sources are coupled in parallel, and may include the magnetic field portions 111 and 113, a gas injection unit 126, a gas injecting extension 133, and electrodes 140A and 140B. The ion source of the present embodiment is different from the tenth embodiment in terms of the positions of the gas injection unit 126 and the gas injecting extension 133, and the voltage sources PS and PD which supply power to the electrodes 140A and 140B.

In the ion source of the fourteenth embodiment, the gas injection unit 126 and the gas injecting extension 133 are disposed between the two single-loop ion sources. The voltage sources PS and PD includes a power supply PS and a power distributor PD. When the power supply PS outputs a DC voltage, the power distributor PD converts the DC voltage to a unipolar pulsed output voltage to supply a positive voltage and a zero voltage alternately to each loop.

In a multi-loop ion source, when the unipolar pulsed voltage is applied to the electrodes 140A and 140B of each loop, argon ions (Ar+) tend to move to the substrate while shifting to a central region between the loops by a voltage bias or the like. Therefore, a desired effect may be obtained as well by injecting the deposition gas ionized by the argon ions (Ar+) into the central region in front of the multi-loop ion source. Of course, the position of the gas injection unit 126 and the gas injecting extension 133 are not limited to the central region between the two single-loop ion sources, but the gas injection unit 126 and the gas injecting extension 133 may be disposed in the inner magnetic pole of each loop.

In the ion source of the fourteenth embodiment, when the power distributor PD applies the unipolar pulsed voltage to the electrodes 140A and 140B, the electric field applied to the argon ions (Ar+) repeats generation and disappearance, so that the total amount of the electric field applied to the argon ions (Ar+) may be reduced. As a result, the argon ions (Ar+) collide less strongly on the substrate, and the surface damage of the substrate may be reduced.

FIGS. 15A and 15B depict that the gas injecting extension 133 has a single opening at its front opening end, but the configuration of the front opening end is not limited thereto. For example, the inner gas injecting extension 133 may further include a T-shaped flow path changing portion at the front opening end. The flow path changing portion may be formed to have a shape which is the same as or similar to the gas injecting extension 133, for example, a plate having slits therein that is open upwards and downwards.

FIG. 16 illustrates a deposition apparatus including an ion source according the present disclosure.

The deposition apparatus may include a process chamber 100, a carrier 200, a substrate 300, an ion source 400, a deposition gas injector 500, and a process gas injector 600.

The process chamber 100 forms a closed interior space for thin film deposition. A vacuum pump is coupled to one side of the process chamber 100, and the vacuum pump is capable of maintaining the internal space at a predetermined process pressure. In the process chamber 100, a reaction gas or deposition gas is injected along with a process gas depending on the process. Examples of the reaction or deposition gas may include nitrogen (N2), oxygen (O2), methane (CH4), tetrafluoromethane (CF4), and silane (SiH4), and the process gas may be argon, neon, helium, or xenon.

The carrier 200 supports the substrate 300 to face the ion source 400, and moves the substrate 300 in a predetermined direction.

The ion source 400 may employ one of the ion sources of the first through fourteenth embodiments described above.

The deposition gas injector 500 supplies the reaction gas such as nitrogen (N2) and oxygen (O2) or the deposition gas such as acetic acid (CH3COOH), methane (CH4), tetrafluoromethane (CF4), silane (SiH4), ammonia (NH3), and tri-methyl aluminum (TMA) into the process chamber 100. The deposition gas injector 500 is connected to the gas injection units 20 or 120 and the gas injecting extension 130 of the ion source 400 so as to inject the reaction gas or the deposition gas into the process chamber 100 in front of the ion source 400.

The process gas injector 600 supplies the process gas such as argon (Ar) into the process chamber 100. The process gas injector 600 may be coupled to the side of the process chamber 100, but the position is not limited thereto.

In the deposition apparatus having such a configuration, the ion source 400 ionizes the process gas injected from the process gas injector 600, first, to produce plasma ions. The ion source 400 may form a plasma region at an open side by using an electric field and a magnetic field formed by the electrode 400 and the magnetic poles 11, 13, 111 or 113. The ion source 400 ionizes the process gas in the plasma region and moves the ionized plasma ions, e.g. argon ions (Ar+), toward the substrate 300 by the electric field of the electrode 40. The moving argon ions (Ar+) ionize the deposition gas to produce deposition ions, e.g. silicon ions (Si⁴⁻). Here, the deposition gas is injected into the front central region of the ion source 400 through the gas injection unit 20 or 120 and the gas injecting extension 130. The deposition ions migrate to the substrate 300 and are deposited on the substrate 300.

While various exemplary embodiments have been described above with reference to the figures, it should be understood that the embodiments should be considered in a descriptive sense only and not for purposes of limitation. Those of ordinary skill in the art would understand that many obvious changes or modifications in form and details may be made therein based on the exemplary embodiments described above without departing from the spirit of the present disclosure. However, such changes and modifications should be construed to be within the scope of the following claims.

### INDUSTRIAL APPLICABILITY

The ion beam source according to the present disclosure can be used for an ion beam processing apparatus and the like and is applicable, as a core technology related to thin film processing, to industrial fields such as a thin film solar cell, a flexible display, a transparent display, a touch screen panel, a functional architectural glass, and an optical device which require a process such as surface modification, surface cleaning, pre-treatment, thin film deposition, etching, and post-treatment of a workpiece.

What is claimed is:

1. An ion source, comprising:
a magnetic field portion having an open side directing toward a workpiece and a closed side, wherein an inner magnetic pole and an outer magnetic pole are disposed to be spaced apart from each other at the open side and the closed side is connected to a magnetic core so that an accelerating closed loop of plasma electrons is formed at the open side, and the inner magnetic pole has a gas injection portion configured to supply gas toward the accelerating closed loop; and
an electrode disposed at a lower portion of the acceleration closed loop with being spaced apart from the magnetic field portion.

2. The ion source of claim 1, wherein the gas injection portion comprises:
a gas inlet configured to receive a gas from outside;
a gas distribution portion connected to the gas inlet in fluid communications and formed along a longitudinal direction of the inner magnetic pole, and having a greater cross-section than the gas inlet; and
a first gas injection portion formed along the longitudinal direction of the inner magnetic pole, having an end connected to the gas distribution portion in fluid communications and another end being open toward the accelerating closed loop, and configured to be a slit shape having a smaller cross-section than the gas distribution portion so as to inject the gas toward the accelerating closed loop.

3. The ion source of claim 1, wherein the gas injection portion comprises:
a second gas injection portion formed along the longitudinal direction of the inner magnetic pole, having an end connected to the gas distribution portion in fluid communications and another end being open toward the workpiece, and having a smaller cross-section than the gas distribution portion so as to inject the gas toward the workpiece.

4. The ion source of claim 3, wherein the second gas injection portion comprises a plurality of through holes or consecutive slits.

5. An ion source, comprising:
a magnetic field portion having an open side directing toward a workpiece and another side, wherein an inner magnetic pole and an outer magnetic pole are disposed to be spaced apart from each other at the open side and the another side is connected to a magnetic core so that a plasma ignition and electron acceleration region is formed at the open side, and the inner magnetic pole or the outer magnetic pole has a gas injection portion having a side that is open toward the workpiece;
a gas injecting extension being coupled to but electrically insulated from the inner magnetic pole or the outer magnetic pole, being connected to the gas injection portion in fluid communications, and protruding toward the workpiece, and
an electrode disposed in the magnetic field portion with being spaced apart from the inner magnetic pole and the outer magnetic pole.

6. The ion source of claim 5, wherein the gas injecting extension is made from an electrically isolating material.

7. The ion source of claim 5, wherein the gas injecting extension comprises:
an electrically-insulating member coupled to the inner magnetic pole or the outer magnetic pole and having a first though hole connected to the gas injection portion in fluid communications; and
a piping member coupled to the electrically-insulating member and having an end connected to the first though hole in fluid communications and another end being open toward the workpiece.

8. The ion source of claim 7, wherein the piping member has a recess in a boundary region contacting with the electrically-insulating member.

9. The ion source of claim 7, wherein the electrically-insulating member has a recess in a boundary region contacting with the piping member, the inner magnetic pole, or the outer magnetic pole.

10. The ion source of claim 5, wherein the gas injecting extension comprises:
a flow path changing portion at an end in a direction toward the workpiece.

11. The ion source of claim 5, wherein the plasma ignition and electron acceleration region forms multiple closed loops.

12. The ion source of claim 5, further comprising:
multiple electrodes; and
a power distributor configured to generate a DC, AC, or pulsed output voltage and output to the multiple electrodes.

13. The ion source of claim 5, wherein the gas injection portion comprises:
a gas inlet configured to receive a gas from outside;
a gas distribution portion connected to the gas inlet in fluid communications and formed along a longitudinal direction of the inner magnetic pole or the outer magnetic pole, and having a greater cross-section than the gas inlet; and
a gas injection portion formed along the longitudinal direction of the inner magnetic pole or the outer magnetic pole, having an end connected to the gas distribution portion in fluid communications and another end being open toward the workpiece, and having a smaller cross-section than the gas distribution portion.

14. The ion source of claim 13, wherein the gas injection portion comprises a plurality of through holes or consecutive slits.

15. A deposition apparatus, comprising:
a process chamber;
an ion source installed in the process chamber and including: a magnetic field portion having an open side directing toward a workpiece and another side, wherein an inner magnetic pole and an outer magnetic pole are disposed to be spaced apart from each other at the open side and the another side is connected to a magnetic core so that a plasma ignition and electron acceleration region is formed at the open side, and the inner magnetic pole or the outer magnetic pole has a gas injection portion having a side that is open toward the workpiece; a gas injecting extension being coupled to but electrically insulated from the inner magnetic pole or the outer magnetic pole, being connected to the gas injection portion in fluid communications, and protruding toward the workpiece, and an electrode disposed in the magnetic field portion with being spaced apart from the inner magnetic pole and the outer magnetic pole;
a first gas injector configured to inject a reaction gas or a deposition gas through the gas injection portion; and
a second gas injector configured to inject a process gas into the process chamber.

16. The deposition apparatus of claim 15, wherein the plasma ignition and electron acceleration region forms multiple closed loops.

17. The deposition apparatus of claim 16, further comprising:
multiple electrodes; and
a power distributor configured to generate a DC, AC, or pulsed output voltage to output to the multiple electrodes.

18. The ion source of claim 2, wherein the gas injection portion comprises:
a second gas injection portion formed along the longitudinal direction of the inner magnetic pole, having an end connected to the gas distribution portion in fluid communications and another end being open toward the workpiece, and having a smaller cross-section than the gas distribution portion so as to inject the gas toward the workpiece.

19. The ion source of claim 18, wherein the second gas injection portion comprises a plurality of through holes or consecutive slits.
